(19) United States
(12) Patent Application Publication
(10) Pub. No.: US 2012/0228122 A1
(43) Pub. Date: Sep. 13, 2012

(54) SPUTTERING APPARATUS AND ELECTRONIC DEVICE MANUFACTURING METHOD

(75) Inventor: Takashi MINAMI, Kawasaki-shi (JP)

(73) Assignee: CANON ANELVA CORPORATION, Kawasaki-shi (JP)

(21) Appl. No.: 13/418,629

(22) Filed: Mar. 13, 2012

Related U.S. Application Data
(63) Continuation of application No. PCT/JP2009/006640, filed on Dec. 4, 2009.

(51) Int. Cl. C23C 14/34

(52) U.S. Cl. 204/192.1; 204/298.11

(57) ABSTRACT

A sputtering apparatus includes a target holder arranged in a vacuum chamber and holds a target to be deposited on a substrate, a substrate holder arranged in the vacuum chamber and supports the substrate, a shutter interposed between the target holder and the substrate holder, and that can set a closed state in which the shutter shields the substrate holder and target holder from each other, and an open state in which the shutter releases the space between the substrate holder and the target holder, a shutter support member which supports the shutter, and a joint mechanism interposed between the shutter support member and the shutter, and that can set a state in which the joint mechanism disconnects the shutter and shutter support member to be able to rotate the shutter, and a state in which the joint mechanism couples and fixes the shutter and shutter support member.

### TECHNICAL FIELD

The present invention relates to a sputtering apparatus used to deposit a material on a substrate in the process of manufacturing a semiconductor device, magnetic storage medium, or the like, and an electronic device manufacturing method.

### BACKGROUND ART

A sputtering apparatus for depositing a thin film on a substrate includes a vacuum chamber which is evacuated to vacuum, a target holder for holding a target made of a material to be deposited on the substrate within the vacuum chamber, and a substrate holder for supporting the substrate. In the process of depositing a thin film on a substrate, the sputtering apparatus introduces a gas such as Ar gas into the vacuum chamber, and applies a high voltage to the target, generating a plasma. The sputtering apparatus attaches the target material to the substrate supported by the substrate holder by utilizing sputtering of the target by charged particles in the discharge plasma.

Positive ions in the plasma enter a negatively charged target material, sputtering atomic molecules of the target material from it. These atomic molecules are called sputtered particles. The sputtered particles attach to the substrate, forming a target material-containing film on the substrate. In the sputtering apparatus, a freely openable shield plate called a shutter is generally interposed between the target material and the substrate.

The shutter is used mainly for the following three purposes. First, the shutter is used to prevent scattering of sputtered particles until discharge stabilizes. More specifically, in the sputtering apparatus, a plasma is generated not at the same time as application of a high voltage, but a delay time of about 0.1 sec after voltage application in general. Even if a voltage is applied, no plasma may be generated, or even if a plasma is generated, it may be unstable immediately after the start of discharge. These phenomena inhibit deposition at a stable film thickness with stable film quality. To avoid this problem, the shutter is used to execute so-called pre-sputtering of starting discharge while closing the shutter, and after discharge stabilizes, opening the shutter to deposit sputtered particles on a substrate.

Second, the shutter is used to perform conditioning inside the vacuum chamber. Conditioning is discharge executed not for deposition on a substrate but for stabilization of plasma characteristics.

For example, before the start of continuous deposition for production, discharge is executed under the same conditions as continuous deposition conditions to stabilize the atmosphere inside the vacuum chamber. It is important to set the inner surface of the vacuum chamber in the same state as that of continuous deposition for stable deposition especially in a reactive sputtering method of depositing an oxide or nitride of a target material using an introduced gas which is a reactive gas such as nitrogen gas or oxygen gas or a gas mixture of a reactive gas and an inert gas such as Ar gas.

However, sputtered particles attach not only to the inner surface of the vacuum chamber but also to the substrate support surface of the substrate holder. The sputtered particles attached to the substrate support surface of the substrate holder attach to even the lower surface of a transferred substrate, causing metal contamination. To prevent this, while closing the shutter to prevent deposition of a film on the substrate support surface, discharge is performed after introducing an inert gas and a reactive gas into the vacuum chamber by using the shutter which is arranged near the substrate holder to shield the substrate support surface of the substrate holder when viewed from the sputtering surface of the target without shielding the inner surface of the vacuum chamber. Accordingly, a nitride or oxide attaches to the inner surface of the vacuum chamber. After the nitride or oxide satisfactorily attaches to the inner surface of the vacuum chamber, deposition on the substrate starts. This can stabilize the quality of a deposited thin film.

In conditioning, discharge is sometimes executed under conditions different from production conditions during continuous deposition for production. For example, if a high-stress film is continuously deposited on a substrate by the reactive sputtering method, a film attached to an attachment prevention shield or the like inside the vacuum chamber peels and serves as particles. To prevent this, a metal film may be periodically deposited by sputtering by introducing only an inert gas without introducing a reactive gas. For example, in continuous deposition of TiN, conditioning of Ti deposition is periodically executed. If only TiN is deposited continuously, the TiN film attached to the attachment prevention shield or the like inside the vacuum chamber peels. However, periodical conditioning of TiN deposition can prevent this.

Third, the shutter is used when a contaminated or oxidized target surface is sputtered in advance to remove a contaminated or oxidized portion of the target before continuous deposition for production. More specifically, when manufacturing a target, the target is molded by machining using a lathe or the like in the final process. At this time, a contaminant generated from a grinding tool attaches to the target surface, or the target surface is oxidized during transportation of the target. It is necessary to sufficiently sputter the target surface and expose a clean target surface before deposition. In this case, the shutter is used for so-called target cleaning of performing sputtering while closing the shutter to prevent attachment of contaminated or oxidized target particles to the substrate support surface of the substrate holder.

Patent literature 1 discloses a technique in which a shutter plate is interposed between a substrate holder and a target and is movable by a moving mechanism.

### CITATION LIST

### Patent Literature

PTL1: Japanese Patent Laid-Open No. 2002-302763

### SUMMARY OF INVENTION

### Technical Problem

However, even if the shutter covers the substrate support surface of the substrate holder as in the above-described technique, a small amount of sputtered particles passes through a gap formed around the shutter and attaches to the substrate support surface of the substrate holder. That is, sputtered particles attach to the substrate support surface of the substrate holder during conditioning or target cleaning, and further attach to the lower surface of the substrate, contaminating the substrate. The metal-contaminated substrate is transported to the next process, and contaminates other manufacturing apparatuses in the next and subsequent processes.

### Solution to Problem

The present invention has been made to overcome the conventional drawbacks, and has as its object to provide a sputtering apparatus capable of preventing attachment of sputtered particles to the substrate support surface of a substrate holder when performing discharge for conditioning, pre-sputtering, and target cleaning.

To achieve the above object, there is provided a sputtering apparatus comprising:

a target holder which is arranged in a vacuum chamber and holds a target to be deposited on a substrate;

a substrate holder which is arranged in the vacuum chamber and supports the substrate;

a substrate holder driving mechanism which rotates the substrate holder;

a shutter which can shield the target holder and the substrate holder from each other,

a shutter support member which supports the shutter;

an open/close drivable shutter driving mechanism which drives the shutter support member in a first direction to drive the shutter to a position in an open state in which the shutter releases a space between the substrate holder and the target holder, and drives the shutter support member in a second direction to drive the shutter to a position in a closed state in which the shutter shields the substrate holder and the target holder from each other; and

a joint mechanism which is interposed between the shutter support member and the shutter, and can set a state in which the shutter at the position in the closed state and the substrate holder are moved close to each other to disengage the shutter support member and the shutter, the shutter is set on the substrate holder, and the substrate holder driving mechanism can freely rotate the substrate holder supporting the shutter while maintaining the shutter at the position in the closed state, or a state in which the shutter at the position in the closed state and the substrate holder are moved apart from each other to engage the shutter support member and the shutter, and the shutter support member can be moved in the first direction together with the shutter.

Alternatively, to achieve the above objection, there is provided an electronic device manufacturing method using a sputtering apparatus including:

a target holder which is arranged in a vacuum chamber and holds a target to be deposited on a substrate;

a substrate holder which is arranged in the vacuum chamber and supports the substrate;

a substrate holder driving mechanism which rotates the substrate holder;

a shutter which can shield the target holder and the substrate holder;

a shutter support member which supports the shutter;

an open/close drivable shutter driving mechanism which drives the shutter support member in a first direction to drive the shutter to a position in an open state in which the shutter releases a space between the substrate holder and the target holder, and drives the shutter support member in a second direction to drive the shutter to a position in a closed state in which the shutter shields the substrate holder and the target holder from each other; and

a joint mechanism which is interposed between the shutter support member and the shutter, and can set a state in which the shutter at the position in the closed state and the substrate holder are moved close to each other to disengage the shutter support member and the shutter, the shutter is set on the substrate holder, and the substrate holder driving mechanism can freely rotate the substrate holder supporting the shutter while maintaining the shutter at the position in the closed state, or a state in which the shutter at the position in the closed state and the substrate holder are moved apart from each other to engage the shutter support member and the shutter, and the shutter support member can be moved in the first direction together with the shutter, comprising:

a deposition preparation step of setting the shutter on the substrate holder by the substrate holder driving mechanism and the shutter driving mechanism while maintaining the shutter at the position in the closed state, supplying power to the target holder, and performing sputtering for deposition preparation; and

a deposition step of, after the deposition preparation step, moving the shutter to the position in the open state by the substrate holder driving mechanism and the shutter driving mechanism, supplying power to the target holder, and performing deposition by sputtering on the substrate set on the substrate holder.

### Advantageous Effects of Invention

The present invention can prevent sputtered particles from reaching the substrate support surface of a substrate holder via a gap formed around a shutter and attaching to it. Also, the present invention can prevent contamination of other manufacturing apparatuses in the next and subsequent processes by a substrate which has been contaminated by the reaching sputtered particles and transported to the next process.

Further features of the present invention will become apparent from the following description of exemplary embodiments with reference to the accompanying drawings. Note that the same reference numerals denote the same or similar parts throughout the accompanying drawings.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1A is a schematic view of a deposition apparatus according to an embodiment of the present invention;

FIG. 1B is a block diagram of a main control unit for operating the deposition apparatuses shown in FIG. 1A;

FIG. 1C is a view for explaining a modification of the deposition apparatus according to the embodiment;

FIG. 1D is a view for explaining a modification of the deposition apparatus according to the embodiment;

FIG. 2 is a sectional view for explaining a state in which a substrate shutter is set on a substrate holder;

FIG. 3 is a sectional view for explaining a state in which the substrate shutter moves up;

FIG. 4 is a sectional view for explaining a modification of a joint mechanism;

FIG. 5 is a sectional view for explaining a modification of the substrate shutter;

FIG. 6 is a sectional view for explaining a modification of the substrate shutter;

FIG. 7 is a view for explaining a modification of the substrate shutter and a substrate periphery cover ring;

FIG. 8 is a view for explaining a modification of a sputtering apparatus;

FIG. 9 is a view showing the schematic arrangement of a flash memory multilayered film formation apparatus as an example of a vacuum thin film formation apparatus according to the present invention; and

FIG. 10 is a flowchart exemplifying a sequence to process an electronic device product using the sputtering apparatus according to the present invention.

### DESCRIPTION OF EMBODIMENTS

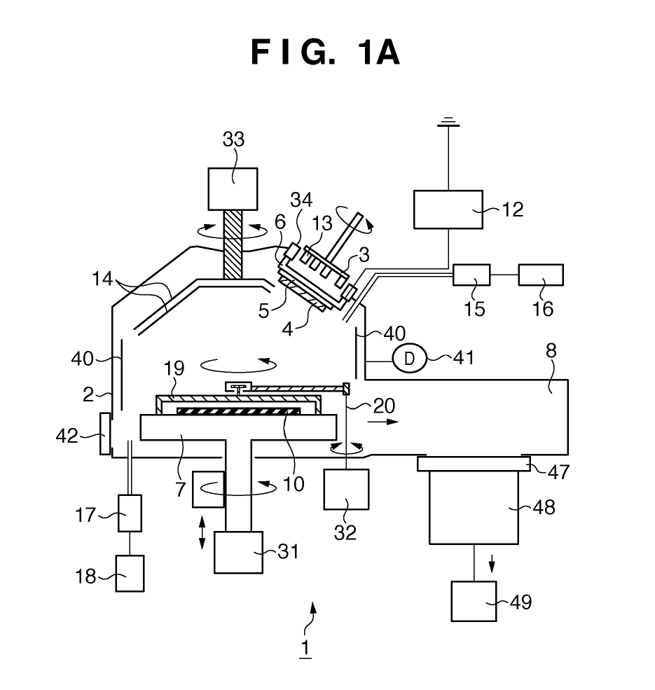

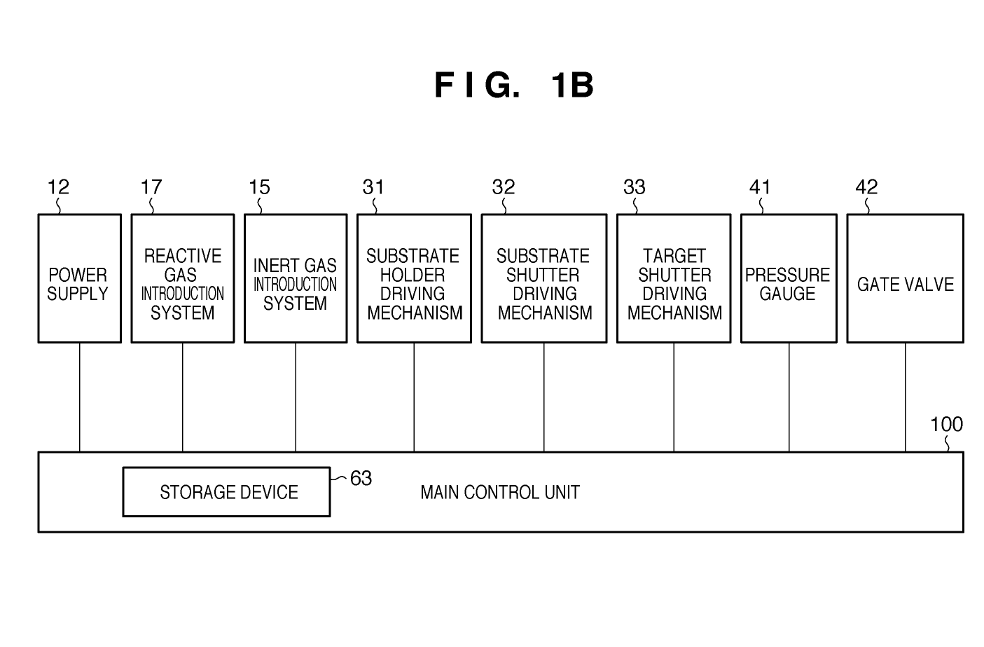

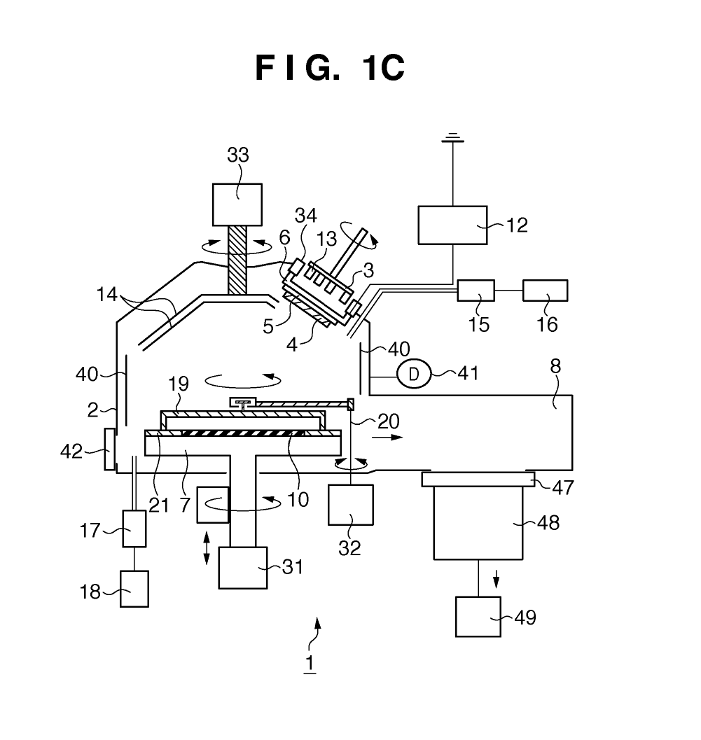

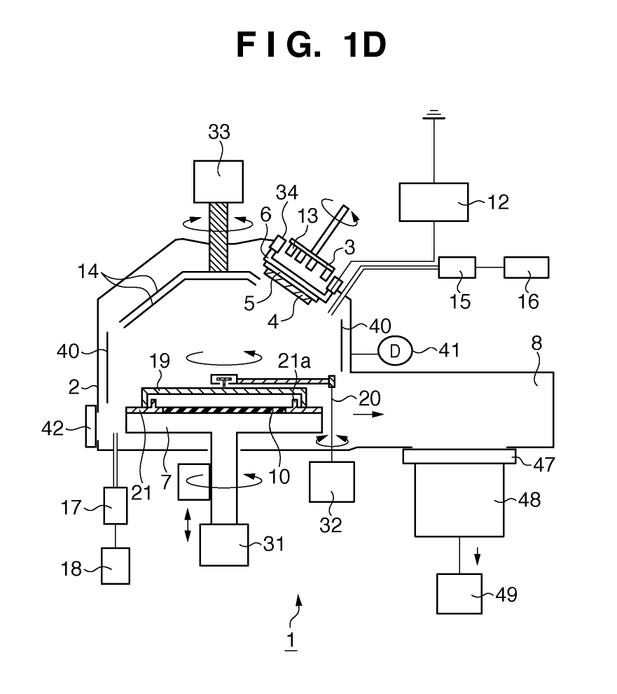

The overall arrangement of a sputtering apparatus (to be also referred to as a “deposition apparatus”) will be explained with reference to FIGS. 1A to 1D, 2, and 3. FIG. 1A is a schematic view of a deposition apparatus 1 according to an embodiment of the present invention. The deposition apparatus 1 includes a vacuum chamber 2, an evacuation device including a turbo molecular pump 48 and dry pump 49 for evacuating the vacuum chamber 2 via an exhaust port 8, an inert gas introduction system 15 capable of introducing an inert gas into the vacuum chamber 2, and a reactive gas introduction system 17 capable of introducing a reactive gas.

The exhaust port 8 is, for example, a conduit with a rectangular section, and connects the vacuum chamber 2 and turbo molecular pump 48. A main valve 47 is interposed between the exhaust port 8 and the turbo molecular pump 48 to disconnect the deposition apparatus 1 from the turbo molecular pump 48 in maintenance.

The inert gas introduction system 15 is connected to an inert gas supply device (gas cylinder) 16 for supplying the inert gas. The inert gas introduction system 15 includes a pipe for introducing the inert gas, a massflow controller for controlling the flow rate of the inert gas, valves for stopping or starting supply of the gas, and if necessary, a pressure reducing valve, filter, and the like. The inert gas introduction system 15 can stably supply the gas at a flow rate designated by a control device. The inert gas is supplied from the inert gas supply device 16, and after its flow rate is controlled by the inert gas introduction system 15, introduced near a target 4 (to be described later).

The reactive gas introduction system 17 is connected to a reactive gas supply device (gas cylinder) 18 for supplying the reactive gas. The reactive gas introduction system 17 includes a pipe for introducing the reactive gas, a massflow controller for controlling the flow rate of the inert gas, valves for stopping or starting the flow of the gas, and if necessary, a pressure reducing valve, filter, and the like. The reactive gas introduction system 17 can stably supply the gas at a flow rate designated by a control device.

The reactive gas is supplied from the reactive gas supply device 18, and after its flow rate is controlled by the reactive gas introduction system 17, introduced near a substrate holder 7 which holds a substrate 10 (to be described later). The inert gas and reactive gas are introduced into the vacuum chamber 2, used to generate sputtered particles or form a film, and then exhausted by the turbo molecular pump 48 and dry vacuum pump 49 via the exhaust port 8.

The vacuum chamber 2 incorporates a target holder 6 which holds, via a back plate 5, the target 4 whose surface to be sputtered is exposed. Also, the vacuum chamber 2 incorporates the substrate holder 7 which holds the substrate 10 at a predetermined position where sputtered particles discharged from the target 4 reach. Further, the vacuum chamber 2 includes a pressure gauge 41 for measuring the pressure of the vacuum chamber 2. The inner surface of the vacuum chamber 2 is grounded. A grounded cylindrical shield 40 (attachment prevention shield member) is arranged on the inner surface of the vacuum chamber 2 between the target holder 6 and the substrate holder 7. The shield 40 (attachment prevention shield member) prevents sputtered particles from directly attaching to the inner surface of the vacuum chamber 2.

A magnet 13 for implementing magnetron sputtering is arranged behind the target 4 when viewed from the sputtering surface. The magnet 13 is held by a magnet holder 3 and is rotatable by a magnet holder rotating mechanism (not shown). The magnet 13 rotates during discharge to uniform erosion of the target.

The target 4 is set at a position (offset position) obliquely above the substrate 10. The center point of the sputtering surface of the target 4 exists at a position shifted by a predetermined distance from the normal of the center point of the substrate 10. In this specification, this sputtering will be called “oblique sputtering”. A power supply 12 is connected to the target holder 6 to apply sputtering discharge power. The deposition apparatus 1 shown in FIG. 1A includes a DC power supply, but is not limited to this and may include, for example, an RF power supply. When the RF power supply is adopted, a matching unit needs to be interposed between the power supply 12 and the target holder 6.

An insulator 34 insulates the target holder 6 from the vacuum chamber 2. The target holder 6 made of a metal (conductive member) such as Cu functions as an electrode upon receiving DC or RF power. As is well known, the target 4 is formed from a material component to be deposited on the substrate 10. The target 4 desirably has high purity because its purity is related to the film purity. The back plate 5 interposed between the target 4 and the target holder 6 is made of a metal such as Cu and holds the target 4.

A target shutter 14 is arranged near the target holder 6 so that it can cover the target holder 6. The target shutter 14 has a rotating shutter structure capable of independently opening/closing the respective shutter members. The target shutter 14 functions as a shield member for setting a closed state in which the target shutter 14 shields the substrate holder 7 and target holder 6 from each other, or an open state in which it releases the space between the substrate holder 7 and the target holder 6. A target shutter driving mechanism 33 opens/closes the target shutter 14.

The substrate holder 7 is connected to a substrate holder driving mechanism 31 for vertically moving the substrate holder 7 and rotating it at a predetermined speed. The substrate holder driving mechanism 31 can vertically move the substrate holder 7 so as to move the substrate holder 7 up toward a substrate shutter 19 (first shield member) in the closed state or down from the substrate shutter 19.

The dish-like substrate shutter 19 with a peripheral portion 19a is interposed between the substrate holder 7 and the target holder 6 near the substrate 10. The substrate shutter 19 is supported by a substrate shutter support member 20 to cover the upper surface of the substrate 10 with the projecting peripheral portion 19a of the substrate shutter 19 facing down (side facing the substrate holder 7). A substrate shutter driving mechanism 32 rotates the substrate shutter support member 20 to insert the substrate shutter 19 between the target 4 and the substrate 10 at a position above the upper surface of the substrate 10 and set the substrate shutter 19 on the substrate holder 7 (closed state). The target 4 and substrate 10 are shielded from each other by inserting the substrate shutter 19 between them and setting the substrate shutter 19 on the substrate holder 7. When the substrate shutter driving mechanism 32 operates to retract the substrate shutter 19 from between the target holder 6 (target 4) and the substrate holder 7 (substrate 10), the space between the target holder 6 (target 4) and the substrate holder 7 (substrate 10) is released (open state). The substrate shutter driving mechanism 32 drives the substrate shutter 19 to set it in the closed state in which the substrate shutter 19 shields the substrate holder 7 and target holder 6 from each other or the open state in which it releases the space between them.

The substrate shutter 19 can retract into the exhaust port 8. The apparatus area can be preferably decreased when the retraction location of the substrate shutter 19 fits within the conduit of the exhaust path extending to the high-vacuum exhaust turbo molecular pump 48, as shown in FIG. 1A.

The substrate shutter 19 is made of stainless steel or an aluminum alloy. When heat resistance is required, the substrate shutter 19 is sometimes formed from titanium or a titanium alloy. The surface of the substrate shutter 19 or at least a surface facing the target 4 undergoes blasting such as sand blasting and has small corrugations. This structure can make difficult peeling of a film attached to the substrate shutter 19, reducing particles generated upon peeling. Note that a metal thin film may be formed on the surface of the substrate shutter 19 by metal spraying or the like, instead of blasting. Thermal spraying is more expensive than blasting, but is advantageous because an attached film including a thermal sprayed film can be removed in maintenance when dismounting the substrate shutter 19 and removing the attached film. Further, a thermal sprayed thin film relaxes the stress of a sputtered film, preventing peeling of the film.

In the arrangement of the deposition apparatus 1 shown in FIG. 1A, the substrate shutter 19 is set on the substrate holder 7 to achieve the closed state. However, the gist of the present invention is not limited to this example, and arrangements as shown in FIGS. 1C and 1D are also possible.

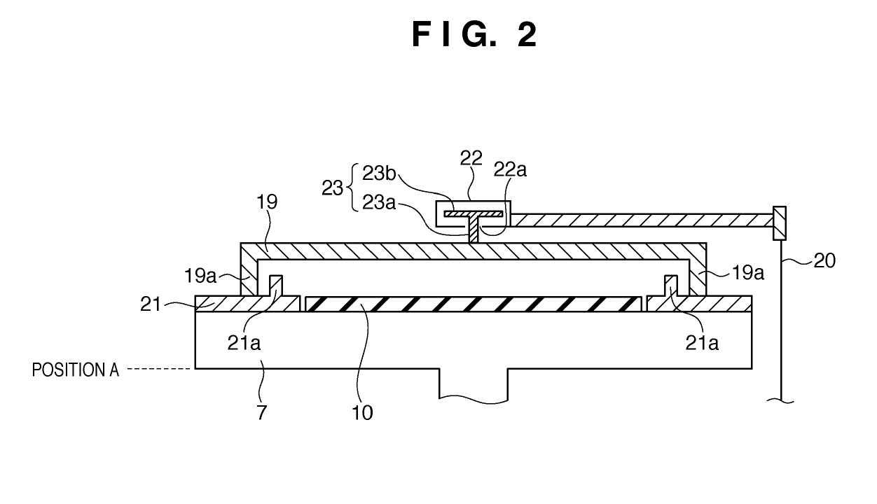

For example, a ring-shaped second shield member (to be referred to as a “substrate periphery cover ring 21”) is arranged at an outer edge (periphery) around a portion at which the substrate 10 is set on the surface of the substrate holder 7. The substrate shutter 19 can be set on the substrate periphery cover ring 21 (FIG. 1C). In the arrangement shown in FIG. 1C, the substrate shutter 19 is inserted between the target 4 and the substrate 10, and set on the substrate periphery cover ring 21, obtaining the closed state. The substrate periphery cover ring 21 can prevent attachment of sputtered particles to a location other than the deposition surface of the substrate 10 set on the substrate holder 7. A location other than the deposition surface includes the surface of the substrate holder 7 covered with the substrate periphery cover ring 21 and the side surface and lower surface of the substrate 10. The substrate periphery cover ring 21 can include a ring-like projection 21a (FIGS. 1D and 2).

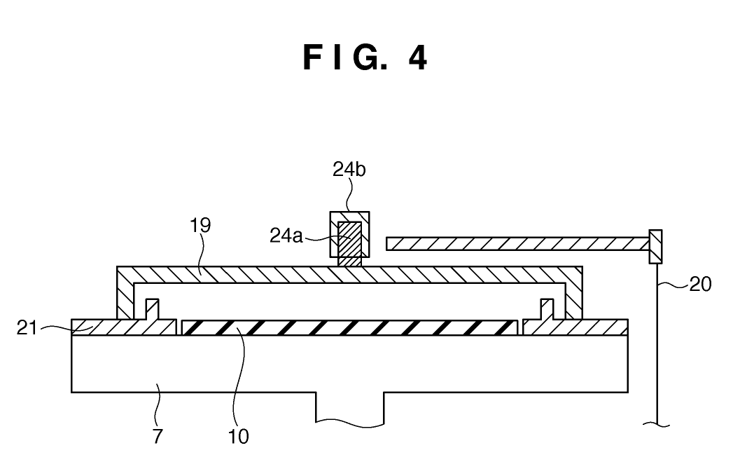

Note that the following description and the explanatory views (FIGS. 4, 5, 6, and 8) of modifications of the substrate shutter will be based on the arrangement of FIG. 1D to avoid a repetitive description. However, the gist of the present invention is not limited to this example, and a modification of the substrate shutter is also applicable to the arrangements of FIGS. 1A and 1C.

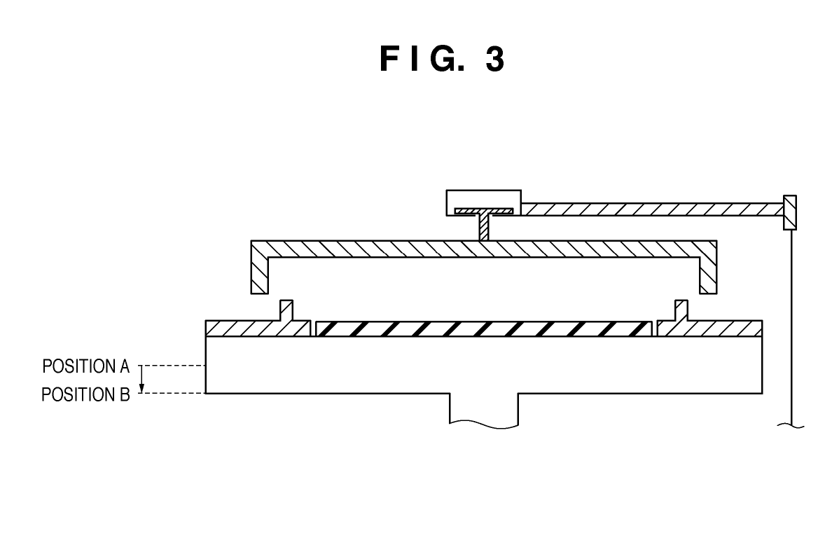

The detailed arrangement of the substrate shutter 19, which is a feature of the present invention, will be explained with reference to FIGS. 2 and 3. FIG. 2 is a sectional view for explaining a state in which the substrate shutter 19 is set on the substrate holder 7. The state shown in FIG. 2 is a contact state in which the projecting peripheral portion 19a of the substrate shutter 19 contacts the substrate periphery cover ring 21 in the closed state in which the substrate shutter 19 is interposed between the target holder 6 and the substrate holder 7 and shields them from each other. The state in FIG. 2 is advantageous because attachment of sputtered particles to the substrate support surface of the substrate holder 7 is prevented in the conditioning process (process of attaching sputtered particles to the inner wall of the chamber) executed before deposition processing on the substrate. FIG. 3 is a sectional view for explaining a state in which the substrate shutter 19 moves up from the substrate holder 7. The state in FIG. 3 indicates a standby position in a noncontact state in which the projecting peripheral portion 19a of the substrate shutter 19 does not contact the substrate periphery cover ring 21 in the closed state in which the substrate shutter 19 is interposed between the target holder 6 and the substrate holder 7 and shields them from each other.

As shown in FIG. 2, the substrate shutter 19 has a dish shape with the projecting peripheral portion 19a. The substrate shutter 19 covers the entire substrate 10 by setting the peripheral portion 19a on the substrate periphery cover ring 21. A hook 23 including a column 23a coupled to the substrate shutter 19 and a plate-like member 23b coupled to the column 23a is arranged at the center of the outer bottom surface of the substrate shutter 19. A hollow box-like engaging portion 22 to be engaged with the hook 23 is arranged at the distal end of the substrate shutter support mechanism 20 configured to support the substrate shutter 19. A through hole 22a is formed in the bottom of the engaging portion 22 so that the column 23a of the hook 23 extends through it. In the state shown in FIG. 2, the plate-like member 23b of the hook 23 is disengaged from the engaging portion 22 and does not contact it. In this state, the substrate shutter 19 can freely rotate together with the substrate holder 7. Even when the substrate holder driving mechanism 31 rotates the substrate holder 7, the substrate shutter 19 on the substrate holder 7 can rotate together with the substrate holder 7 without any constraint by the engaging portion 22. In the embodiment, a “joint mechanism” is formed from the engaging portion 22 and hook 23.

As shown in FIG. 3, when the substrate shutter support mechanism 20 drives the substrate shutter 19 to move up from the substrate holder 7, the plate-like member 23b of the hook 23 and the bottom of the engaging portion 22 contact each other (are coupled). In this coupling state, the substrate shutter 19 is lifted up by the substrate shutter support mechanism 20 via the joint mechanism formed from the engaging portion 22 and hook 23, and separated from the substrate holder 7. As a feature, the joint mechanism according to the embodiment is free from a problem such as generation of dust upon contact between the plate-like member 23b and the bottom of the engaging portion 22 even if the rotatable state as in FIG. 2 and the engaging state as in FIG. 3 are repeated because the plate-like member 23b is surrounded by the hollow box-like engaging portion 22. Note that the substrate shutter support mechanism 20 drives the substrate shutter 19 to move up from the substrate holder 7. However, the substrate holder driving mechanism 31 may move down the substrate holder 7 from the substrate shutter 19. Even this method has the same feature as the above one.

FIG. 1B is a block diagram of a main control unit 100 for operating the deposition apparatuses 1 shown in FIGS. 1A, 1C, and 1D. The main control unit 100 is electrically connected to the power supply 12 for applying sputtering discharge power, the inert gas introduction system 15, the reactive gas introduction system 17, the substrate holder driving mechanism 31, the substrate shutter driving mechanism 32, the target shutter driving mechanism 33, the pressure gauge 41, and a gate valve 42. The main control unit 100 is configured to be able to manage and control the operation of the deposition apparatus 1 (to be described later).

Note that a storage device 63 in the main control unit 100 stores a control program for executing, for example, a method of deposition on a substrate, including conditioning and sputtering according to the present invention. For example, the control program is implemented as a mask ROM. The control program can also be installed in the storage device 63 formed from a hard disk drive (HDD) or the like via an external recording medium or network.

Next, the procedures of a deposition method using the deposition apparatus 1 according to the embodiment of the present invention will be explained.

(Operation in Conditioning)

The operation of the deposition apparatus 1 in conditioning will be explained. Conditioning processing is processing of performing discharge to stabilize deposition characteristics and attaching sputtered particles to the inner wall of the chamber and the like in the same state as the deposition state of continuous deposition while closing the substrate shutter 19 not to affect deposition on the substrate.

First, the main control unit 100 instructs the substrate shutter driving mechanism 32 to close the substrate shutter 19. Then, the main control unit 100 instructs the target shutter driving mechanism 33 to close the target shutter 14 (third shield member). In response to the instructions from the main control unit 100, the target shutter 14 and substrate shutter 19 are closed. In this state, the substrate holder 7 is set at position B (FIG. 3) serving as the standby position.

The main control unit 100 instructs the substrate holder driving mechanism 31 to execute a move-up operation. In response to this, the substrate holder 7 moves up from position B (FIG. 3) serving as the standby position to a position (position A: FIG. 2) where the substrate shutter 19 is set on the substrate holder 7 and the plate-like member 23b of the hook 23 and the engaging portion 22 are disengaged from each other (shutter closing step).

After that, the main control unit 100 instructs a control device which controls the inert gas introduction system 15, to introduce an inert gas (for example, Ar, Ne, Kr, or Xe gas) from the inert gas introduction system 15 near the target 4 while closing the target shutter 14, as shown in FIGS. 1A, 1C, and 1D. The inert gas introduced near the target 4 raises the pressure near the target 4, compared to that near the substrate 10, so discharge readily occurs. In this state, the power supply 12 applies power to the target 4 to start discharge. At this time, the substrate shutter 19 is set on the substrate periphery cover ring 21 (substrate holder 7) and can prevent attachment of sputtered particles to the substrate support surface of the substrate holder 7.

The main control unit 100 drives the target shutter driving mechanism 33, and instructs it to open the target shutter 14. In response to this, conditioning to the inner wall of the chamber starts. Sputtered particles flying out from the target 4 attach to the inner wall of the chamber, depositing a film. When the shield 40 is formed on the inner wall, sputtered particles attach to the surface of the shield 40, depositing a film. The substrate shutter 19 is set on the substrate periphery cover ring 21 and can prevent sputtered particles from reaching the substrate support surface of the substrate holder 7. In this state, so-called conditioning is executed to form a film on the inner wall of the chamber or the building member such as the shield 40. Executing conditioning can stabilize reaction between the sputtered particles and the reactive gas when the shutter is opened. At this time, when performing conditioning by reactive sputtering discharge, the reactive gas is introduced from the reactive gas introduction system 17 toward the substrate. When the holder driving mechanism 31 rotates the substrate holder 7, even the substrate shutter 19 rotates together with the substrate holder 7 because the substrate shutter 19 is set on the substrate periphery cover ring 21. This rotation can uniform localization of films attached to the substrate shutter 19 and substrate holder 7 upon oblique sputtering. The rotation is preferable because it can prolong the maintenance cycle, compared to not rotating the substrate shutter 19.

After discharge for a predetermined time, the main control unit 100 instructs the power supply 12 to stop application of power, thereby stopping the discharge. At this time, films are deposited on the shield 40, target shutter 14, substrate shutter 19, and another surface facing the target.

The main control unit 100 instructs the control device which controls the inert gas introduction system 15, to stop supply of the inert gas. When the reactive gas is supplied, the main control unit 100 also instructs the reactive gas introduction system 17 to stop supply of the reactive gas. Then, the main control unit 100 instructs the target shutter driving mechanism 33 to close the target shutter 14 (rotating shutter).

The main control unit 100 instructs the substrate holder driving mechanism 31 to move the substrate holder 7 from position A (FIG. 2) to position B (FIG. 3). Thereafter, conditioning is complete.

By the above procedures, conditioning can be performed while preventing sputtered particles from reaching the substrate support surface of the substrate holder 7. After the conditioning process, the substrate shutter driving mechanism 32 opens the substrate shutter 19, and the sputtering deposition process is executed.

Note that the operation in target cleaning of removing an impurity or oxide attached to the target before deposition can be executed by the same procedures as the above-described procedures of the operation in conditioning. However, target cleaning can be performed even while closing the target shutter 14 after the start of discharge. In this case, target cleaning can prevent contamination of the inner surface of the shield 40 by an impurity or oxide attached to the target before deposition. Target cleaning can be further executed after the target shutter 14 is opened. In this case, target cleaning has an effect of prolonging the replacement cycle of the target shutter 14, that is, the maintenance cycle. An impurity or contaminant is discharged much more from the target surface at the initial stage of target cleaning. To stabilize subsequent deposition, target cleaning is often performed somewhat excessively. If target cleaning is done for a long time while the target shutter 14 is kept closed, a large amount of deposit attaches to a surface of the target shutter 14 that faces the target, generating particles. This shortens the replacement cycle of the target shutter 14. To avoid this, when contamination of the shield 40 is not so significant, the target shutter 14 is opened to perform target cleaning. It is also possible to perform target cleaning while closing the target shutter 14, then open the target shutter 14, and further continue target cleaning.

In the above procedures, the substrate holder driving mechanism 31 drives the substrate holder 7 to vertically move it, thereby changing the relative position of the substrate shutter 19 and substrate holder 7 to position A (FIG. 2) or position B (FIG. 3). However, the gist of the present invention is not limited to this. For example, the substrate shutter driving mechanism 32 can drive the substrate shutter 19 to vertically move it, thereby changing the relative position of the substrate shutter 19 and substrate holder 7 to position A (FIG. 2) or position B (FIG. 3).

(Pre-sputtering Operation and Deposition on Substrate)

A pre-sputtering operation and the operation of the deposition apparatus 1 when performing deposition on the substrate will be explained. All deposition on the substrate 10 is executed after performing pre-sputtering. Pre-sputtering is sputtering performed to stabilize discharge while closing the substrate shutter 19 and target shutter 14 not to affect deposition on the substrate.

First, the main control unit 100 instructs the substrate shutter driving mechanism 32 to close the substrate shutter 19 (set the relative position to position A (FIG. 2)). Then, the main control unit 100 instructs the target shutter driving mechanism 33 to close the target shutter 14 (rotating shutter). In response to this, the target shutter 14 (rotating shutter) and substrate shutter 19 are closed. In this state the substrate holder 7 is set at position B (FIG. 3) serving as the standby position.

After that, the main control unit 100 opens the gate valve 42 of the chamber wall, and designates loading of the substrate 10 via the gate valve 42 by a substrate transfer mechanism (not shown) outside the chamber. The substrate 10 is loaded between the substrate shutter 19 and the substrate periphery cover ring 21. Further, the substrate 10 is set on the substrate support surface of the substrate holder 7 by cooperation between the substrate transfer mechanism outside the chamber and a lift mechanism (not shown) in the substrate holder 7.

The main control unit 100 closes the gate valve 42, and instructs the substrate holder driving mechanism 31 to move the substrate holder 7 from position B (FIG. 3) to position A (FIG. 2).

Subsequently, the main control unit 100 drives the substrate holder driving mechanism 31 to rotate the substrate holder 7 and at the same time, rotate even the substrate shutter 19 set on the substrate holder 7. The inert gas introduction system 15 arranged near the target introduces an inert gas (for example, Ar, Ne, Kr, or Xe gas). The main control unit 100 instructs the power supply 12 to apply power to the target, thereby starting discharge. Since sputtering starts while setting the substrate shutter 19 on the substrate holder 7, attachment of sputtered particles to the substrate 10 can be prevented.

After a predetermined discharge stabilization time (3 to 15 sec) for stabilizing discharge, the main control unit 100 opens the target shutter 14 and starts pre-sputtering. At this time, if an error such as a failure to start discharge occurs, the main control unit 100 can detect it by monitoring the discharge voltage current, and stop the deposition sequence. If no problem occurs, the target shutter 14 is opened as described above, and sputtered particles attach to the inner wall of the chamber, depositing a film. When performing deposition by reactive sputtering, the reactive gas introduction system 17 near the substrate introduces a reactive gas. Sputtered particles attach to the shield surface of the shield 40, depositing a film.

After pre-sputtering for a necessary time, the main control unit 100 instructs the substrate holder driving mechanism 31 to move the substrate holder 7 from position A (FIG. 2) to position B (FIG. 3). The main control unit 100 instructs the substrate shutter driving mechanism 32 to open the substrate shutter 19 and start deposition on the substrate 10.

After discharge for a predetermined time, the main control unit 100 stops application of power to stop the discharge, and also stops supply of the inert gas. When the reactive gas is supplied, the main control unit 100 stops even supply of the reactive gas. A gate valve (not shown) in the chamber is opened, and the substrate is unloaded in an order reverse to the loading order, completing pre-sputtering and deposition processing on the substrate.

By operating the shutter mechanism according to the above procedures, entrance of sputtered particles to the substrate can be prevented, and a high-quality film can be formed. In the opening operation of the substrate shutter 19, the substrate is rotated in advance. Simultaneously when the substrate shutter 19 is opened, a film excellent in in-plane uniformity can be deposited, improving the throughput.

The embodiment can provide a sputtering apparatus which prevents attachment of sputtered particles to the substrate support surface of the substrate holder when performing discharge for conditioning, pre-sputtering, and target cleaning.

(First Modification)

A joint mechanism in the first modification is formed from a bearing (shaft 24a and bearing 24b), as shown in FIG. 4. More specifically, a bearing using a magnetic fluid can prevent friction because the fluid is used, suppressing generation of particles.

(Second Modification)

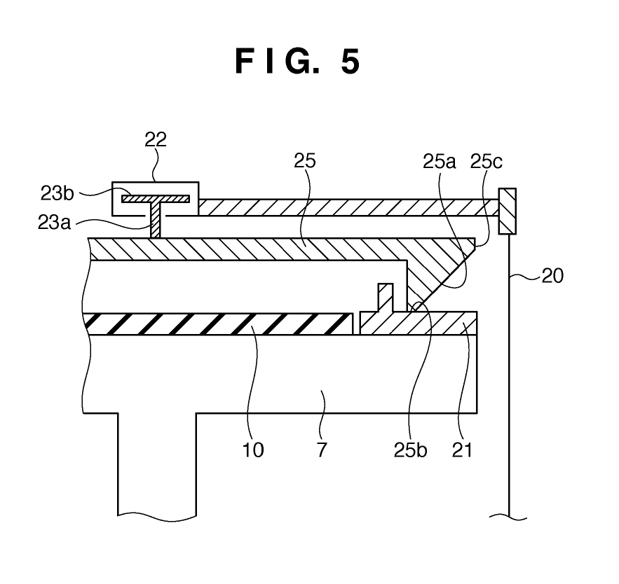

As shown in FIG. 5, a notched portion 25a is formed from an upper wall portion 25b to lower end portion 25c of a shutter 25 at the periphery of the substrate shutter 25 in the second modification. The notched portion 25a is desirably formed at the entire periphery of the substrate shutter 25. Decreasing the contact area between the substrate periphery cover ring 21 and the shutter 25 can suppress peeling of a film deposited on the substrate periphery cover ring 21 upon deposition on the substrate 10.

When viewed from the target 4, the notched portion 25a hides the boundary between the substrate periphery cover ring 21 and the substrate shutter 25 in a state in which they contact each other. Thus, deposition at the boundary is reduced in conditioning discharge, suppressing generation of particles from the boundary when the contact between the substrate periphery cover ring 21 and the substrate shutter 25 is canceled. These two synergistic effects of this shape can further suppress generation of particles.

(Third Modification)

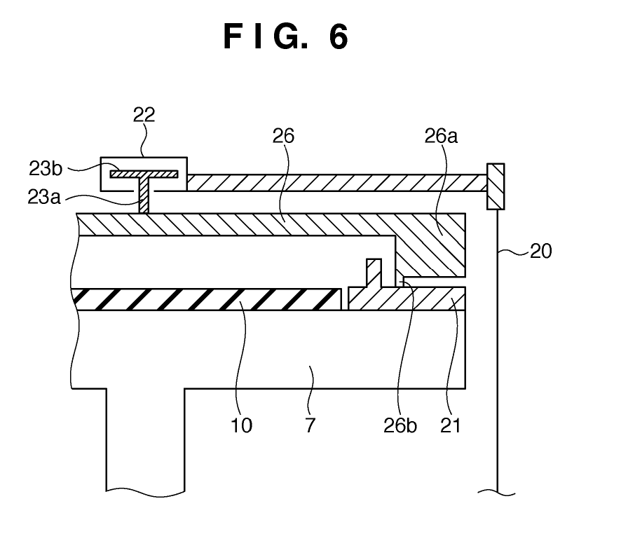

As shown in FIG. 6, a notched portion 26b is formed at a periphery 26a of a substrate shutter 26 in the third modification to form a gap between the periphery 26a and the substrate periphery cover ring 21. More specifically, the contact area between the substrate periphery cover ring 21 and the substrate shutter 26 is decreased, and the periphery 26a of the substrate shutter 26 covers the contact portion. This structure makes it difficult for sputtered particles to reach the contact portion.

The substrate shutter with a shape as shown in FIG. 6 can prevent attachment of a film at the contact portion between the substrate shutter 26 and the substrate periphery cover ring 21. Peeling of a film upon opening the shutter 26 can be suppressed.

(Fourth Modification)

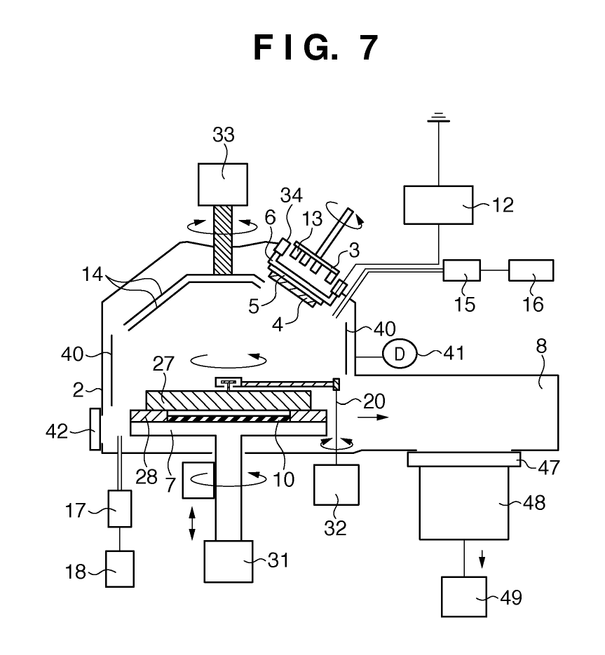

The substrate shutter is not limited to the dish-like one as described above, and a plate-like substrate shutter 27 is also available, as shown in FIG. 7. In this case, a contact surface of the substrate periphery cover ring 21 that contacts the bottom surface of the substrate shutter needs to be formed at higher level than the upper surface of the substrate.

(Fifth Modification)

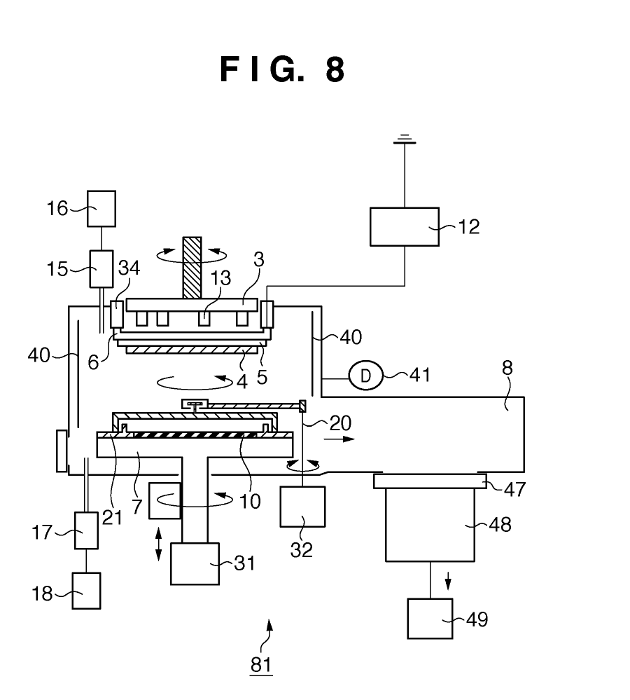

Unlike the deposition apparatus 1 shown in FIG. 1D, a sputtering apparatus shown in FIG. 8 has an arrangement in which the target 4 stationarily faces the substrate 10. A deposition apparatus 81 according to the fifth modification basically has the same arrangement as that of the deposition apparatus 1 shown in FIG. 1D. The same reference numerals denote the same parts, and a detailed description thereof will be omitted. One of the arrangements in the second to fourth modifications described above is applicable to the deposition apparatus 81 according to the fifth modification. Effects obtained by the modification can be implemented in the fifth modification.

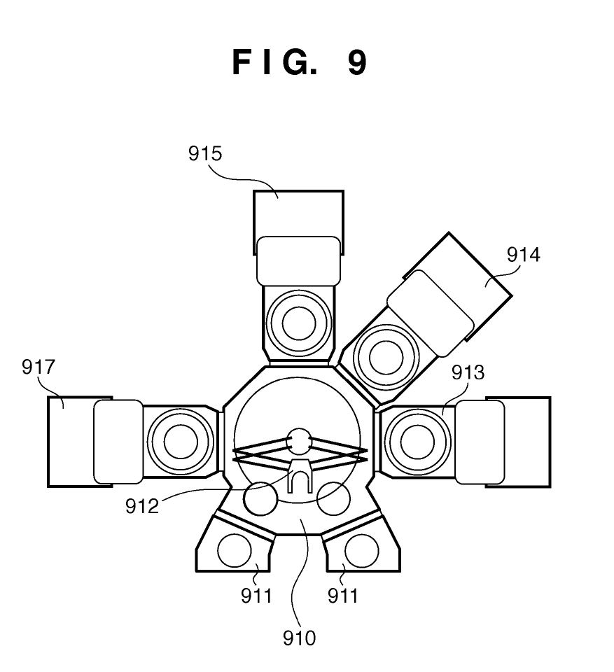

FIG. 9 is a view showing the schematic arrangement of a flash memory multilayered film formation processing apparatus (to be also simply referred to as a “multilayered film formation apparatus”) as an example of a vacuum thin film formation apparatus according to the embodiment of the present invention. The multilayered film formation apparatus shown in FIG. 9 includes a vacuum transfer chamber 910 which incorporates a vacuum transfer robot 912. Load-lock chambers 911, a substrate heating chamber 913, a first PVD (sputtering) chamber 914, a second PVD (sputtering) chamber 915, and a substrate cooling chamber 917 are coupled to the vacuum transfer chamber 910 via gate valves, respectively. Each of the first PVD (sputtering) chamber 914 and second PVD (sputtering) chamber 915 can employ one of the deposition apparatuses 1 shown in FIGS. 1A, 1C, and 1D.

The operation of the multilayered film formation apparatus shown in FIG. 9 will be explained. First, a substrate (silicon wafer) to be processed is set in the load-lock chamber 911 for loading/unloading the substrate into/from the vacuum transfer chamber 910, and the load-lock chamber 911 is evacuated until the pressure reaches 1×10⁻⁴ Pa or less. By using the vacuum transfer robot 912, the substrate is loaded into the vacuum transfer chamber 910 in which the degree of vacuum is maintained at 1×10⁻⁶ Pa or less, and then transferred to a desired vacuum processing chamber.

In the embodiment, the substrate is first transferred to the substrate heating chamber 913 and heated to 400° C. Then, the substrate is transferred to the first PVD (sputtering) chamber 914 to deposit an Al₂O₃ thin film on the substrate at a thickness of 15 nm. The substrate is transferred to the second PVD (sputtering) chamber 915 to deposit a TiN film on the substrate to a thickness of 20 nm. Finally, the substrate is transferred to the substrate cooling chamber 917 and cooled to room temperature. After the end of all processes, the substrate is returned to the load-lock chamber 911, and after dry nitrogen gas is introduced to reach the atmospheric pressure, unloaded from the load-lock chamber 911. In the multilayered film formation apparatus according to the embodiment, the degree of vacuum in the vacuum processing chamber is set to 1×10⁻⁶ Pa or less. The embodiment adopts magnetron sputtering for deposition of the Al₂O₃ film and TiN film.

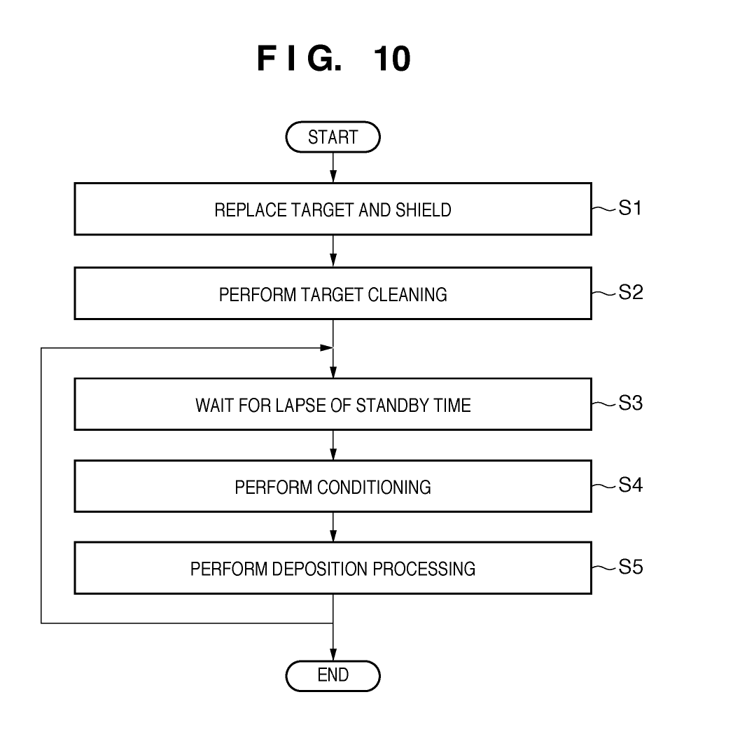

FIG. 10 is a flowchart for explaining an example of a sequence to process an electronic device product using the deposition apparatus 1 according to the embodiment of the present invention.

In step S1, the target and shield are replaced, and then the interior of the vacuum chamber 2 is evacuated and controlled to a predetermined pressure. After the interior of the vacuum chamber 2 reaches the predetermined pressure, target cleaning is executed in step S2 by sputtering for preparations of deposition processing to be executed in step S5. As described above, target cleaning is performed by setting the substrate shutter 19 on the substrate periphery cover ring 21. This can prevent attachment of sputtered particles to the substrate support surface of the substrate holder 7. Note that target cleaning may be executed while the substrate 10 is set on the substrate holder 7.

In step S3, the process waits for the lapse of a predetermined time in order to execute processes in step S4 and subsequent step (wait for the lapse of the standby time). In the manufacture of an electronic device, deposition processing can hardly start immediately after target cleaning owing to the standby time of the product or the like, and the standby time is often required as in step S3.

In step S4, conditioning is executed by sputtering for preparations of deposition processing to be executed in step S5. Conditioning processing is processing of performing discharge to stabilize deposition characteristics and attaching sputtered particles to the inner wall of the chamber and the like in the same state as the deposition state of continuous deposition while closing the substrate shutter 19 not to affect deposition on the substrate.

In step S5, after conditioning in step S4, deposition processing on the substrate 10 starts by opening the substrate shutter 19 and supplying power to the target 4. At this time, the number of products to be continuously processed varies from one to several hundred. After the continuous processing, the standby time may be generated.

If the standby time is generated, conditioning in step S4 is executed again. By this conditioning, a low-stress film of Ti or the like can cover the upper surface of a high-stress film of TiN or the like attached to the inner surface of the shield. If TiN continuously attaches to the shield, the film peels and serves as particles because the TiN film has high stress and weak adhesion to the shield. To prevent film peeling, Ti is sputtered.

The Ti film has strong adhesion to the shield and TiN film, and has an effect (wall paint effect) of preventing peeling of the TiN film. In this case, the substrate shutter is effectively used for sputtering on the entire shield. The deposition apparatus 1 according to the embodiment of the present invention can perform conditioning without depositing a sputtered film on the substrate support surface of the substrate holder because of a structure in which no gap is formed between the substrate shutter and the substrate periphery cover ring. After conditioning, deposition processing is performed.

As described above, conditioning is executed after the standby time, and then the product processing procedures are repeated till the end of the service life of the target. After maintenance is performed to replace the shield and target, the procedures are repeated from target cleaning at the initial stage.

By the above-described procedures, an electronic device can be manufactured while preventing peeling of a film attached to the shield without attaching sputtered particles to the substrate support surface of the substrate holder 7. In the embodiment, maintenance is performed at the end of the service life of the target. However, when even conditioning cannot prevent peeling of a film from the shield, maintenance may be performed before the end of the service life of the target. In this case, only the shield is replaced without replacing the target. In the embodiment, conditioning starts every time the standby time is generated. However, the conditioning start condition is not limited to the embodiment.

A difference in effects corresponding to the substrate shutter shape will be explained by referring to the following examples.

### Example 1

An example in which the deposition apparatus according to the present invention is applied to prevent peeling of TiN from the chamber wall by periodically depositing Ti on the chamber wall will be explained. The deposition apparatus is the apparatus (FIG. 1A, 1C, or 1D) described in the embodiment. A target 4 uses Ti. A substrate shutter 19 has the shape shown in FIG. 2.

Conditioning discharge (lot pre-sputtering) before TiN deposition was performed for 1,200 sec under TiN deposition conditions (to be described later). Then, a wafer obtained by forming an SiO₂ (1.5 nm)/HfSiO (1.5 nm) multilayered film on a 300-mmφ Si substrate was set on a substrate holder 7 of the deposition apparatus 1, and a TiN film was deposited to have a thickness of 7 nm.

The TiN deposition conditions at this time are as follows.

Ar gas was supplied as an inert gas at 20 sccm (sccm: standard cc per minute, the unit of the flow rate of the gas to be supplied per minute in conversion into cm³ at 0° C. and 1 atm as the standard state). N₂ gas was supplied as a reactive gas at 20 sccm, a pressure of 0.04 Pa, and power of 700 W for 240 sec.

The Si substrate was unloaded. Further, the same deposition was performed for 300 Si substrates, the Si substrates were unloaded, and the process ended.

After that, conditioning processing was performed. Ar gas was supplied at 50 sccm, a pressure of 0.04 Pa, and power of 1,000 W to start discharge. A target shutter 14 was opened, and conditioning discharge was performed for 2,400 sec while the substrate shutter 19 was kept closed.

In general, no substrate (Si substrate) is set on the substrate holder 7 in conditioning. In this example, however, a 300-mm Si bare substrate was set on the substrate support surface of the substrate holder 7, and discharge was performed.

After the end of the discharge, the 300-mm Si bare substrate on the substrate holder 7 was unloaded, and a portion of 26 to 34 mm from the substrate end was analyzed using a total-reflection X-ray fluorescence analysis apparatus TXRF (Total-reflection X-Ray Fluorescence: TREX630IIIx available from Technos) to find out that the detected Ti amount was equal to or smaller than the detection limit.

### Example 2

To examine effects when the substrate shutter shape was different from that in Example 1, an experiment was conducted using the deposition apparatus 1 under the same conditions as those in Example 1 except that a substrate shutter 25 (second modification) having a different peripheral shape as in FIG. 5 was used. The experiment under the same conditions as those in Example 1 revealed that the detected Ti amount was 2×10¹⁰ atms/cm².

### Comparative Example

For comparison, a conditioning discharge experiment was conducted under the same conditions except for an apparatus in which a substrate shutter 19 did not contact a substrate periphery cover ring 21 and neither the substrate periphery cover ring 21 of a substrate holder 7 nor the substrate shutter 19 had a projection. As a result, a Ti film was formed at the periphery of the substrate to a degree at which the Ti film could be visually confirmed. The formed Ti film was thick and could not be measured by the TXRF. Hence, the film thickness was measured by observing the section using a TEM (Transmission Electron Microscope) to find out that the film thickness was about 5 nm. Note that the 5-nm thickness of the Ti film is equivalent to 3×10¹⁶ atms/cm² upon calculation using a Ti density of 4.5. From this, it was confirmed that a larger amount of sputtered particles reached the substrate support surface in the comparative example in which the substrate shutter 19 and substrate periphery cover ring 21 did not contact each other, compared to Examples 1 and 2 in which they contacted each other.

Examples 1 and 2 and the comparative example are summarized in table 1. Note that the Ti amount in the comparative example is a value converted from the film thickness.

TABLE 1

| | Contact between | | |
|---|---|---|---|
| | Substrate | | |
| | Shutter and | Peripheral | |
| | Substrate | Shape of | |
| | Periphery Cover | Substrate | Ti Amount |
| | Ring | Shutter | (atms/cm²) |
| Example 1 | ◯ | Linear | ≦Detection |
| | | | limit |
| Example 2 | ◯ | Notched | ≦Detection |
| | | | limit |
| Comparative | X | . . . | 3 × 10¹⁶ |
| Example | | | |

In Examples 1 and 2 in which the substrate shutter 19 and substrate periphery cover ring 21 contacted each other, the Ti amount was much smaller than that in the comparative example in which they did not contact each other.

A preferred embodiment of the present invention has been described with reference to the accompanying drawings. However, the present invention is not limited to the above-described embodiment, and various changes and modifications can be made within the technical scope grasped from the description of the appended claims.

1. A sputtering apparatus characterized by comprising:
a target holder which is arranged in a vacuum chamber and holds a target to be deposited on a substrate;
a substrate holder which is arranged in the vacuum chamber and supports the substrate;
a substrate holder driving mechanism which rotates said substrate holder;
a shutter which can shield said target holder and said substrate holderfrom each other;
a shutter support member which supports said shutter;
an open/close drivable shutter driving mechanism which drives said shutter support member in a first direction to drive said shutter to a position in an open state in which said shutter releases a space between said substrate holder and said target holder, and drives said shutter support member in a second direction to drive said shutter to a position in a closed state in which said shutter shields said substrate holder and said target holder from each other; and
a joint mechanism which is interposed between said shutter support member and said shutter, and can set a state in which said shutter at the position in the closed state and said substrate holder are moved close to each other to disengage said shutter support member and said shutter, said shutter is set on said substrate holder, and said substrate holder driving mechanism can freely rotate said substrate holder supporting said shutter while maintaining said shutter at the position in the closed state, or a state in which said shutter at the position in the closed state and said substrate holder are moved apart from each other to engage said shutter support member and said shutter, and said shutter support member can be moved in the first direction together with said shutter.

2. (canceled)

3. The sputtering apparatus according to claim 1, wherein said substrate holder driving mechanism can move said substrate holder in a direction in which said shutter at the position in the closed state and said substrate holder move close to or apart from each other.

4. The sputtering apparatus according to claim 1, wherein said shutter driving mechanism can move said shutter support member in a direction in which said shutter at the position in the closed state and said substrate holder move close to or apart from each other.

5. The sputtering apparatus according to claim 1, further comprising:
a target shutter which is set to be able to cover said target holder; and
a target shutter driving mechanism which opens and closes said target shutter.

6. An electronic device manufacturing method using a sputtering apparatus including:
a target holder which is arranged in a vacuum chamber and holds a target to be deposited on a substrate;
a substrate holder which is arranged in the vacuum chamber and supports the substrate;
a substrate holder driving mechanism which rotates the substrate holder;
a shutter which can shield the target holder and the substrate holder;
a shutter support member which supports the shutter;
an open/close drivable shutter driving mechanism which drives the shutter support member in a first direction to drive the shutter to a position in an open state in which the shutter releases a space between the substrate holder and the target holder, and drives the shutter support member in a second direction to drive the shutter to a position in a closed state in which the shutter shields the substrate holder and the target holder from each other; and
a joint mechanism which is interposed between the shutter support member and the shutter, and can set a state in which the shutter at the position in the closed state and the substrate holder are moved close to each other to disengage the shutter support member and the shutter, the shutter is set on the substrate holder, and the substrate holder driving mechanism can freely rotate the substrate holder supporting the shutter while maintaining the shutter at the position in the closed state, or a state in which the shutter at the position in the closed state and the substrate holder are moved apart from each other to engage the shutter support member and the shutter, and the shutter support member can be moved in the first direction together with the shutter, comprising:
a deposition preparation step of setting the shutter on the substrate holder by the substrate holder driving mechanism and the shutter driving mechanism while maintaining the shutter at the position in the closed state, supplying power to the target holder, and performing sputtering for deposition preparation; and
a deposition step of, after the deposition preparation step, moving the shutter to the position in the open state by the substrate holder driving mechanism and the shutter driving mechanism, supplying power to the target holder, and performing deposition by sputtering on the substrate set on the substrate holder.

7. (canceled)

8. The electronic device manufacturing method according to claim 6, wherein
the sputtering apparatus further includes:
a target shutter which is arranged in the vacuum chamber and set to be able to cover the target holder; and
a target shutter driving mechanism which opens and closes the target shutter, and
the deposition preparation step includes a target cleaning step of closing the target shutter by the target shutter driving mechanism, sputtering the target set on the target holder, and cleaning the target.

9. The electronic device manufacturing method according to claim 6, wherein the deposition preparation step includes a conditioning step of attaching a sputtered particle to an inner wall of the vacuum chamber.

10. The sputtering apparatus according to claim 1, wherein
said joint mechanism includes an engaging portion of said shutter support member at which said shutter and said substrate holder can be engaged with each other depending on a relative distance between said shutter and said substrate holder, and a hook of said shutter, and
said shutter at the position in the closed state and said substrate holder are moved close to each other to cancel a contact state between said shutter support member and said shutter, and said engaging portion and said hook are disengaged, or
said shutter at the position in the closed state and said substrate holder are moved apart from each other to bring said shutter support member and said shutter into contact with each other, and said engaging portion and said hook are engaged with each other.

11. The electronic device manufacturing method according to claim 6, wherein the deposition preparation step is performed while the substrate holder driving mechanism rotates the substrate holder and rotates the shutter set on the substrate holder.
